(19) United States
(12) Patent Application Publication
(10) Pub. No.: US 2026/0362838 A1
(43) Pub. Date: Nov. 12, 2026

(54) IMAGE SENSOR INCLUDING ELEMENT ISOLATION PATTERN

(71) Applicant: SAMSUNG ELECTRONICS CO., LTD., Suwon-si (KR)

(72) Inventors: Segyo HAN, Suwon-si (KR); Yongjun KIM, Suwon-si (KR); Sunhee YUN, Suwon-si (KR); Sol YOON, Suwon-si (KR); Myungjo JUNG, Suwon-si (KR)

(73) Assignee: SAMSUNG ELECTRONICS CO., LTD., Suwon-si (KR)

(21) Appl. No.: 19/455,374

(22) Filed: Jan. 21, 2026

(30) Foreign Application Priority Data
Jan. 21, 2025 (KR) 10-2025-0009079

(51) Int. Cl. H10F 39/00

(52) U.S. Cl. CPC H10F 39/807; H10F 39/8037

(57) ABSTRACT

An image sensor according to one or more embodiments the present disclosure may include a first element isolation pattern in a substrate adjacent one or more pixel regions, wherein each of the one or more pixel regions include a second element isolation pattern and at least one active region, and the second element isolation pattern is in the substrate and adjacent the at least one active region, a semiconductor pattern in a recess in a surface of the first element isolation pattern, the semiconductor pattern including a polycrystalline semiconductor material, at least one first gate on the semiconductor pattern, and a gate insulating layer between the at least one first gate and the semiconductor pattern.

### CROSS-REFERENCE TO RELATED APPLICATION(S)

This application claims priority under 35 USC § 119 to Korean Patent Application No. 10-2025-0009079, filed on Jan. 21, 2025, in the Korean Intellectual Property Office, the disclosure of which is herein incorporated by reference in its entirety.

### BACKGROUND

The present disclosure relates to an image sensor.

An image sensor is a semiconductor element that converts an optical image into an electrical signal. Recently, with the development of the computer industry and the communication industry, the demand for image sensors with improved performance has increased in various fields such as digital cameras, camcorders, personal communication systems (PCS), gaming devices, security cameras, and medical micro cameras. The Image sensor can be classified into a charge coupled device (CCD) type and a complementary metal oxide semiconductor (CMOS) type. The CMOS type image sensor is provided with a plurality of pixels arranged two-dimensionally. Each of the pixels may include a photodiode (PD). The photodiode may serve to convert light incident into an electrical signal.

The operation method of the image sensor includes a rolling shutter method in which exposure time intervals for each row of a pixel array operate differently, and a global shutter method in which the exposure time intervals for each row of the pixel array operate identically.

### SUMMARY

According to an aspect of the present disclosure, an image sensor may include a first element isolation pattern in a substrate adjacent one or more pixel regions, wherein each of the one or more pixel regions include a second element isolation pattern and at least one active region, and the second element isolation pattern is in the substrate and adjacent the at least one active region, a semiconductor pattern in a recess in a surface of the first element isolation pattern, the semiconductor pattern including a polycrystalline semiconductor material, at least one first gate on the semiconductor pattern, and a gate insulating layer between the at least one first gate and the semiconductor pattern.

According to an aspect of the present disclosure, an image sensor may include an element isolation pattern including an insulating material in a substrate, a semiconductor pattern in a recess in the element isolation pattern and including a polycrystalline semiconductor material, at least one first gate on the semiconductor pattern, at least one second gate on at least one active region adjacent a first side of the element isolation pattern, and a gate insulating layer between the at least one first gate and the semiconductor pattern, and between the at least one second gate and the at least one active region.

According to an aspect of the present disclosure, an image sensor may include an element isolation pattern including an insulating material in a substrate, at least one semiconductor pattern in a recess in the element isolation pattern and including a polycrystalline semiconductor material, a first gate on the at least one semiconductor pattern, a buried gate in the recess and below the at least one semiconductor pattern, a buried gate insulating layer between the buried gate and the at least one semiconductor pattern, and a gate insulating layer between the first gate and the at least one semiconductor pattern.

### BRIEF DESCRIPTION OF DRAWINGS

FIG. 1 is a block diagram of an image sensor according to one or more embodiments of the present disclosure.

FIG. 2 is a diagram showing an operation of a global shutter mode of the image sensor of FIG. 1.

FIG. 3 is a circuit diagram of each of pixels included in a pixel array of an image sensor according to one or more embodiments of the present disclosure.

FIG. 4 is a plan view of an image sensor according to one or more embodiments of the present disclosure.

FIG. 5A is cross-sectional views taken along lines I-I′ and II-II′ of FIG. 4.

FIG. 5B is a cross-sectional view taken along line III-III′ of FIG. 4.

FIGS. 6A, 7A, 8, 9A, 10A, 11A, 12A, 13A, 14A, and 15A are cross-sectional views for showing a method of manufacturing an image sensor according to one or more embodiments of the present disclosure, which are cross-sectional views corresponding to lines I-I′ and II-II′ of FIG. 4.

FIGS. 6B, 7B, 9B, 10B, 11B, 12B, 13B, 14B, 15B, and 16 are cross-sectional views for showing the method of manufacturing the image sensor according to one or more embodiments of the present disclosure, which are cross-sectional views corresponding to line III-III′ of FIG. 4.

FIG. 17A is a cross-sectional view of an image sensor according to one or more embodiments of the present disclosure, which is a cross-sectional view corresponding to line II-II′ of FIG. 4.

FIG. 17B is a cross-sectional view of the image sensor according to one or more embodiments of the present disclosure, which is a cross-sectional view corresponding to line III-III′ of FIG. 4.

FIG. 18A is a cross-sectional view of an image sensor according to one or more embodiments of the present disclosure, which is a cross-sectional view corresponding to line II-II′ of FIG. 4.

FIG. 18B is a cross-sectional view of the image sensor according to one or more embodiments of the present disclosure, which is a cross-sectional view corresponding to line III-III′ of FIG. 4.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “containing”, “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

In addition, in the present disclosure, the meaning of “identical” includes cases where properties are similar to each other or similar within a certain range. Furthermore, unless clearly indicated, stated, and/or shown otherwise; as used herein the terms “identical”, “uniform”, “equal”, and/or “the same” mean “substantially identical”, “substantially uniform”, “substantially equal”, “about the same”, and/or “substantially the same”. The meaning of substantially identical should be understood to include numerical values within manufacturing error ranges, machining or processing tolerances, and/or differences within a range that is so insignificant such that neither the structure nor function of the embodiments disclosed herein are materially altered, inhibited, or destroyed.

Unless otherwise indicated, as used herein with regard to any plurality of a particular type of component, any two components of that type are considered “adjacent” or “adjacent to” one another so long as no other component of that type occupies a space between the two components. That is, the two components are considered adjacent each other if the two components are not separated from each other by an intervening component of that type.

Hereafter, example embodiments of the present disclosure will bed described with reference to the accompanying drawings.

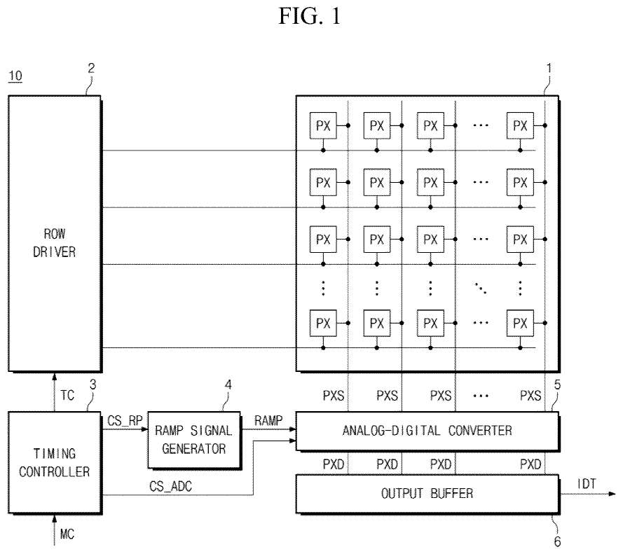

FIG. 1 is a block diagram of an image sensor 10 according to one or more embodiments of the present disclosure.

An image sensor 10 may operate in a global shutter mode or a rolling shutter mode based on a mode control signal. The image sensor 10 may perform both a signal dump operation and a rolling readout operation using a source follower transistor based on a feedback structure in the global shutter mode. In addition, the image sensor 10 may include a capacitor for storing a pixel voltage or a reset voltage in the global shutter mode. Hereinafter, the pixel voltage refers to a voltage output to a column line CL in response to photocharges generated in a photoelectric conversion element comprising a photodiode PD.

Referring to FIG. 1, the image sensor 10 may generate image data which is visual information of an object captured through a lens and an image sensor processor may be implemented to process the image data generated by the image sensor 10 and output it to a display device or store it on a storage device.

The image sensor 10 may include a pixel array 1, a row driver 2, a timing controller 3, a ramp signal generator 4, an analog-digital converter (ADC) 5, and an output buffer 6.

The pixel array 1 may include a plurality of pixels PX. The pixel array 1 may receive a plurality of pixel driving signals such as a selection signal for controlling a selection transistor SEL, a reset signal for controlling a reset transistor RX, and a transfer transistor TX control signal for controlling a transfer transistor TX from the row driver 2. Each of the plurality of pixels PX in the pixel array 1 may operate according to the received pixel driving signals.

The plurality of pixels PX may be arranged, for example, in a matrix form. Each of the pixels PX may be electrically connected to one of a plurality of row lines and one of a plurality of column lines. In one or more embodiments, each of the pixels PX may include a plurality of transistors controlled by the row driver 2.

Each of the plurality of pixels PX may include the photodiode PD that converts an incident light signal into an electrical signal.

The photoelectric conversion element may comprise any one of or a combination of the photodiode PD, a photocapacitor, a photogate, a pinned PD (PPD), a partially PPD, an organic photo diode (OPD), and a quantum dot (QD). Although one or more embodiments of the present specification will be described on the premise that the photoelectric conversion element is the photodiode PD, the above-mentioned other photoelectric conversion elements may be used and the photoelectric conversion element may not necessarily be limited to the photodiode PD.

The row driver 2 may drive one row or a plurality of rows of the pixel array 1 under the control of the timing controller 3. That is, the row driver 2 may drive at least one of the plurality of rows. The row driver 2 may generate a selection signal to drive at least one of the plurality of rows. The row driver 2 may activate the pixels PX corresponding to the selected row. A pixel signal PXS of the pixels of the selected row may be transmitted to the ADC 5 through a plurality of column lines.

The pixel signal PXS may include a reset voltage signal and a pixel voltage signal. The pixel voltage signal may be a voltage of a floating diffusion region FD reflecting charges generated in the PD included in each of the plurality of pixels. The reset voltage signal may be a voltage of the floating diffusion region FD used as a reference voltage for performing correlated double sampling (CDS) with the pixel voltage signal.

The timing controller 3 may control the pixel array 1, the row driver 2, the ramp signal generator 4, and the analog-digital converter 5. The timing controller 3 may provide a timing control signal TC to the row driver 2.

The timing control signal TC may be set differently based on a mode control signal MC. For example, the mode control signal MC is a signal based on a shooting mode selected by a user, and the shooting mode may include a still image mode, a video mode, etc. The mode control signal MC may be a signal that controls the image sensor 10 to operate in the global shutter mode or the rolling shutter mode. In one or more embodiments, the mode control signal MC may be provided from an image signal processor.

The row driver 2 may drive each of the plurality of pixels PX in the global shutter method or the rolling shutter method based on the timing control signal TC. The row driver 2 may output the pixel signal PXS of each of the plurality of pixels PX in both the global shutter method and the rolling shutter method using a signal that controls the source follower transistor.

In one or more embodiments, the row driver 2 may operate the pixel PX to provide a plurality of conversion gain modes. In this case, the pixel PX may generate the pixel voltage signal by applying a high conversion gain (HCG) to the pixel voltage, generate the pixel voltage signal by applying a middle conversion gain (MCG) to the pixel voltage, or generate the pixel voltage signal by applying a low conversion gain (LCG) to the pixel voltage.

The timing controller 3 may control the ramp signal generator 4 through a ramp control signal CS_RP and may control the ADC 5 through an ADC control signal CS_ADC. The ramp control signal CS_RP may include a ramp enable signal, a mode signal, and the like.

The ramp signal generator 4 may generate a ramp signal RAMP corresponding to the ramp control signal CS_RP. The ramp signal generator 4 may generate the ramp signal RAMP having a preset slope. The ramp signal generator 4 may provide the generated ramp signal RAMP to the ADC 5.

The ADC 5 may, based on the ramp signal RAMP, convert the reset voltage signal and the pixel voltage signal of the pixel signal PXS into pixel data PXD which is a digital signal and output the converted pixel data PXD. For example, the ADC 5 may convert each of the reset voltage signal and the pixel voltage signal into the digital signal based on the ramp signal RAMP using a correlated double sampling method, and output the difference between the reset voltage signal and the pixel voltage signal as the pixel data PXD which is the digital signal.

The output buffer 6 may include a plurality of column memory blocks corresponding to each column to store the pixel signal. The output buffer 6 may include a sense amplifier for amplifying the pixel data PXD stored in the column memory block. The sense amplifier may output the amplified pixel data PXD as image data IDT.

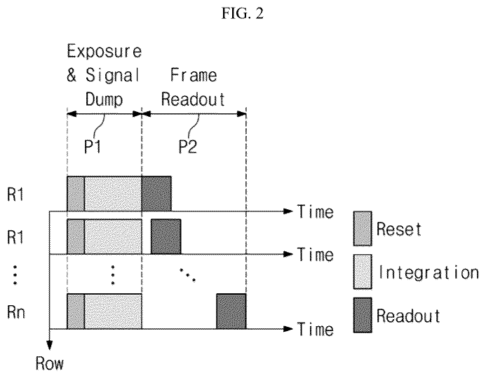

FIG. 2 is a diagram showing an operation of the global shutter mode of the image sensor 10 of FIG. 1.

Referring to FIGS. 1 and 2, when the image sensor 10 operates in the global shutter mode, each pixel PX may be controlled so that photocharge integration time P1 of the photodiode is to be located in the same time section for all pixels of the pixel array 1. The integration time may refer to a time during which the PD actually integrates photocharges. The image sensor 10 may perform a signal dump operation in the photocharge integration time P1. In the global shutter mode, the image sensor 10 may perform a rolling readout operation. For example, the image sensor 10 may control each pixel PX so that the time interval in which a readout is performed after the integration time is different for each row of the pixel array 1. Alternatively, the time section during which the readout is performed may differ for the rows of a certain group. In this case, the readout for the pixels PX of the same group may be performed in the same time section. The time required to read out all pixels PX of the pixel array 1 corresponding to one frame of an image signal may be a frame readout time P2.

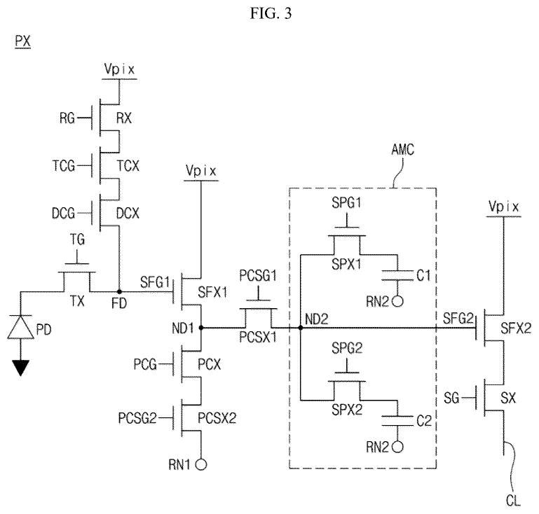

FIG. 3 is a circuit diagram of each of the pixels PX included in the pixel array 1 of the image sensor 10 according to one or more embodiments of the present disclosure.

Referring to FIG. 3, the pixel array 1 may include the plurality of pixels PX, and the pixels PX may be arranged in a matrix form. Each of the pixels PX may include pixel transistors, and the pixel transistors may include a transfer transistor TX and logic transistors. The logic transistors may include a reset transistor RX, a selection transistor SEL, and a source follower transistor SF.

In addition, each of the pixels PX may include a photodiode PD and a floating diffusion region FD. The photodiode PD may generate and integrate photocharges in proportion to amount of light incident from the outside. In the context of the instant image sensor, a “pixel” may be understood as a photodiode PD configured together with at least one transfer transistor gate TG. Although two or more pixels may share among them pixel-driving transistors (e.g., reset transistor, selection transistor, source-follower transistor, dual-conversion gain transistor, etc.) and a single floating diffusion region FD (i.e., the drain of the transfer transistor), as used herein, a “pixel” includes only the transfer transistor gate TG and the photodiode PD (i.e., the source of the transfer transistor). Conversely, neither the pixel-driving transistors nor the floating diffusion region FD are considered part of the “pixel”.

The transfer transistor TX may be connected between the photodiode PD and the floating diffusion region FD. A first terminal of the transfer transistor TX may be connected to an output terminal of the photodiode PD, and a second terminal of the transfer transistor TX may be connected to the floating diffusion region FD. The transfer transistor TX may be turned on or off according to a signal received from the row driver 2 and may transfer the photocharges generated in the photodiode PD to the floating diffusion region FD.

The floating diffusion region FD may have a parasitic capacitance. The floating diffusion region FD may receive and cumulatively store the photocharges generated in the photodiode PD.

The reset transistor RX may periodically reset charges integrated in the floating diffusion region FD. A first terminal of the reset transistor RX may be connected to the floating diffusion region FD, and a second terminal of the reset transistor RX may be connected to a power terminal Vₚᵢₓ. When the reset transistor RX is turned on, a power voltage of the power terminal Vₚᵢₓ may be applied to the floating diffusion region FD through the reset transistor RX. In other words, when the reset transistor RX is turned on, the charges integrated in the floating diffusion region FD may be discharged by the power voltage, thereby resetting the floating diffusion region FD.

Each of the pixels PX may further include at least one conversion gain transistor TCX or DCX. A first terminal of the conversion gain transistor TCX or DCX may be connected to the reset transistor RX, and a second terminal of the conversion gain transistor TCX or DCX may be connected to the floating diffusion region FD.

The reset transistor RX may be turned on or off by a reset control signal received from the row driver 2, and the conversion gain transistor TCX or DCX may be turned on or off in response to a conversion gain control signal received from the row driver 2. When the reset transistor RX and the conversion gain transistor TCX or DCX are turned on, the charges integrated in the floating diffusion region FD may be discharged, thereby resetting the floating diffusion region FD.

The conversion gain transistor TCX or DCX may adjust the parasitic capacitance of the floating diffusion region FD. For example, when the conversion gain transistor TCX or DCX is turned on, the parasitic capacitance of the floating diffusion region FD may be increased, and conversely, when the conversion gain transistor TCX or DCX is turned off, the parasitic capacitance of the floating diffusion region FD may be decreased.

The conversion gain transistor TCX or DCX may be provided as a plurality of conversion gain transistors. Specifically, the conversion gain transistor TCX or DCX may include a dual conversion gain transistor DCX and a triple conversion gain transistor TCX sequentially connected from the floating diffusion region FD toward the reset transistor RX. For example, the dual conversion gain transistor DCX, the triple conversion gain transistor TCX, and the reset transistor RX may be connected in series.

When the dual conversion gain transistor DCX is turned off, the parasitic capacitance of the floating diffusion region FD is decreased, so that the image sensor 10 may operate in the high conversion gain (HCG) mode. Conversely, when the dual conversion gain transistor DCX is turned on, the parasitic capacitance of the floating diffusion region FD is increased, so that the image sensor 10 may operate in the middle conversion gain (MCG) mode.

Furthermore, when both the dual conversion gain transistor DCX and the triple conversion gain transistor TCX are turned on, the parasitic capacitance of the floating diffusion region FD may be further increased, so that the image sensor 10 may operate in the low conversion gain (LCG) mode.

Therefore, the pixel may provide a plurality of conversion gain modes. Therefore, high quality images may be generated.

The source follower transistor SF may include a first source follower transistor SF1 in which a first source follower gate SFG1 is connected to the floating diffusion region FD. A first terminal of the first source follower transistor SF1 may be connected to the power terminal Vₚᵢₓ that may receive the power voltage, and a second terminal of the first source follower transistor SF1 may be connected to a first node Nd1. The first source follower transistor SF1 may be controlled according to an amount of photocharges integrated in the floating diffusion region FD.

The source follower transistor SF may serve as a source follower buffer amplifier. For example, the first source follower transistor SF1 may amplify a change in potential in the floating diffusion region FD and output the amplified change in potential to the first node ND1.

Each of the pixels may further include a first precharge selection transistor PCSEL1, a precharge transistor PCX, and a second precharge selection transistor PCSEL2.

The first precharge selection transistor PCSEL1 may be connected between the first node ND1 and a second node ND2. The first precharge selection transistor PCSEL1 may be turned on or off in response to a first precharge selection signal received from the row driver 2, and may reset the second node ND2. The second node ND2 may have a parasitic capacitance.

A first terminal of the precharge transistor PCX may be connected to the first node ND1, and a second terminal of the precharge transistor PCX may be connected to the second precharge selection transistor PCSEL2. The precharge transistor PCX may precharge the first node ND1 according to a precharge control signal received from the row driver 2.

The second precharge selection transistor PCSEL2 may be connected in series with the precharge transistor PCX. A first terminal of the second precharge selection transistor PCSEL2 may be connected to the precharge transistor PCX, and a first reference voltage of a first reference terminal RN1 may be applied to a second terminal of the second precharge selection transistor PCSEL2. The first reference terminal RN1 may be ground.

The second precharge selection transistor PCSEL2 may be turned on or off in response to a second precharge selection control signal received from the row driver 2 and may reset the first node ND1.

Each of the pixels PX may further include an analog memory circuit AMC. The analog memory circuit AMC may include a first sampling transistor SPX1. A first terminal of the first sampling transistor SPX1 may be connected to the second node ND2, and a second terminal of the first sampling transistor SPX1 may be connected to a first capacitor C1. The first sampling transistor SPX1 may be turned on or off in response to a first sampling control signal received from the row driver 2, and may connect the first capacitor C1 to the second node ND2.

A second reference voltage of a second reference terminal RN2 may be applied to a first terminal of the first capacitor C1, and a second terminal of the first capacitor C1 may be connected to the first sampling transistor SPX1. In one or more embodiments, the second reference voltage may be substantially the same as the power voltage of the power terminal. Charges may be integrated in the first capacitor Cl according to a switching operation of the first sampling transistor SPX1. For example, charges according to a reset operation in which the floating diffusion region FD is reset may be integrated in the first capacitor C1.

The analog memory circuit AMC may include a second sampling transistor SPX2. A first terminal of the second sampling transistor SPX2 may be connected to the second node ND2, and a second terminal of the second sampling transistor SPX2 may be connected to a second capacitor C2. The second sampling transistor SPX2 may be turned on or off in response to a second sampling control signal received from the row driver 2 and may connect the second capacitor C2 to the second node ND2.

The second reference voltage of the second reference terminal RN2 may be applied to a first terminal of the second capacitor C2, and a second terminal of the second capacitor C2 may be connected to the second sampling transistor SPX2. Charges may be integrated in the second capacitor C2 according to a switching operation of the second sampling transistor SPX2. For example, charges according to a photocharge integration operation in which the photocharges generated in the photodiode PD are integrated in the floating diffusion region FD may be integrated in the second capacitor C2.

The source follower transistor SF may include a second source follower transistor SF2 in which a second source follower gate SFG2 is connected to the second node ND2. The power voltage of the power terminal Vₚᵢₓ may be applied to a first terminal of the second source follower transistor SF2, and a second terminal of the second source follower transistor SF2 may be connected to the selection transistor SEL. The second source follower transistor SF2 may amplify and output a change in potential at the second node ND2.

A first terminal of the selection transistor SEL may be connected to the second source follower transistor SF2, and a second terminal of the selection transistor SEL may be connected to a column line CL. The selection transistor SEL may be turned on or off in response to a selection control signal received from the row driver 2. When the selection transistor SEL is turned on, a reset signal corresponding to a reset operation or an image signal corresponding to a charge integration operation may be output to the column line CL.

For example, the second source follower transistor SF2 and the selection transistor SEL may output a pixel signal corresponding to a change in potential at the second node ND2 to the column line CL, and may output a pixel signal corresponding to one of a charge amount stored in the first capacitor C1 and a charge amount stored in the second capacitor C2 through the column line CL.

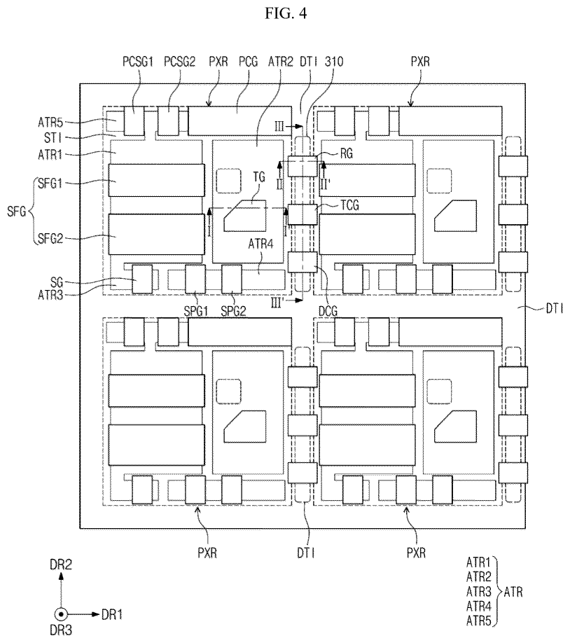

FIG. 4 is a plan view of the image sensor 10 according to one or more embodiments of the present disclosure.

Referring to FIG. 4, the image sensor 10 may include a deep element isolation pattern DTI defining a plurality of pixel regions PXR and a shallow element isolation pattern STI defining at least one active region in each of the pixel regions PXR.

A substrate 100 may have one surface and the other surface. The one surface and the other surface may face each other. For example, the one surface of the substrate 100 may be a front surface of the substrate 100, and the other surface of the substrate 100 may be a back surface of the substrate 100. The substrate 100 may be a semiconductor substrate including silicon, germanium, silicon-germanium, or a compound semiconductor substrate. In one or more embodiments, the substrate 100 may be a silicon substrate.

In one or more embodiments, the deep element isolation pattern DTI may pass through the substrate 100. In other words, the deep element isolation pattern DTI may fill a deep trench DTR that pass through the substrate 100. The deep element isolation pattern DTI may form a substantial grid shape in a plan view. Each of the pixel regions PXR may be a portion of the substrate 100 surrounded by the deep element isolation pattern DTI.

The shallow element isolation pattern STI may be provided in the substrate 100 to define at least one active region in each of the pixel regions PXR. The shallow element isolation pattern STI may fill a shallow trench STR recessed from the one surface of the substrate 100. In other words, the shallow element isolation pattern STI may be provided in the substrate 100 and may be adjacent to the one surface of the substrate 100. The active region may be a portion of the substrate 100 (for example, a portion of the pixel region PXR) surrounded by the shallow element isolation pattern STI in a plan view.

A plurality of active regions may include a first active region ATR1, a second active region ATR2, a third active region ATR3, a fourth active region ATR4, and a fifth active region ATR5. First and second source follower transistors SF1 and SF2 may be provided in the first active region ATR1, and a floating diffusion region FD and a transfer transistor TX may be provided in the second active region ATR2. A selection transistor SEL may be provided in the third active region ATR3, and first and second sampling transistors SPX1 and SPX2 may be provided in the fourth active region ATR4. In addition, first and second precharge selection transistors PCSEL1 and PCSEL2 and a precharge transistor PCX may be provided in the fifth active region ATR5. The third active region ATR3 may be connected to the first active region ATR1. The fifth active region ATR5 may be connected to the first active region ATR1.

More specifically, first and second source follower gates SFG1 and SFG2 may be disposed over the first active region ATR1, a transfer gate TG may be disposed over the second active region ATR2, a selection gate SG may be disposed over the third active region ATR3, and first and second sampling gates SPG1 and SPG2 may be disposed over the fourth active region ATR4. In addition, first and second precharge selection gates PCSG1 and PCSG2 and a precharge gate PCG may be disposed over the fifth active region ATR5.

A photoelectric conversion region PR may be provided in each of the pixel regions PXR. The substrate 100 (for example, each of the pixel regions PXR) may be doped with impurities having a first conductivity type, and the photoelectric conversion region PR may be doped with impurities having a second conductivity type different from the first conductivity type. One of the first conductivity type and the second conductivity type may be a P-type, and the other of the first conductivity type and the second conductivity type may be a N-type. For example, the first conductivity type may be the P-type, and the second conductivity type may be the N-type. Accordingly, the photoelectric conversion region PR and the pixel region PXR surrounding the photoelectric conversion region PR may be a P-N junction forming a photodiode. The floating diffusion FD may be doped with impurities having the second conductivity type.

A semiconductor pattern 310 may be provided in the deep element isolation pattern DTI. Specifically, the semiconductor pattern 310 may be provided in the deep element isolation pattern DTI. The semiconductor pattern 310 may be spaced apart from the active regions ATR1 to ATR5. The semiconductor pattern 310 may include a semiconductor material in an amorphous or polycrystalline state. For example, the semiconductor pattern 310 may include polysilicon, or any other suitable semiconductor material.

The semiconductor pattern 310 may be provided in the deep element isolation pattern DTI provided at one side of the pixel region PXR. For example, the semiconductor pattern 310 may be provided in the deep element isolation pattern DTI defining the pixel region PXR. For example, the semiconductor pattern 310 may be provided in the deep element isolation pattern DTI between one pixel region PXR and another pixel region PXR adjacent to the one pixel region PXR.

The semiconductor pattern 310 may be elongated along the deep element isolation pattern DTI. Specifically, the semiconductor pattern 310 may extend along one side of the grid-shaped deep element isolation pattern DTI. For example, the semiconductor pattern 310 may be elongated in a direction parallel to a second direction DR2.

A reset gate RG may be provided over the semiconductor pattern 310. The reset gate RG may extend over so as to cross or intersect the semiconductor pattern 310 in plan view (i.e., top-down, or layout view). Specifically, the reset gate RG may extend in a first direction DR1 intersecting the second direction DR2. Therefore, the reset transistor RX may be provided in the deep element isolation pattern DTI, and the reset gate RG may be provided over the semiconductor pattern 310 in the deep element isolation pattern DTI.

A dual conversion gain gate DCG may be provided over the semiconductor pattern 310. The dual conversion gain gate DCG may cross the semiconductor pattern 310. Specifically, the dual conversion gain gate DCG may extend in the first direction DR1 intersecting the second direction DR2. Therefore, the dual conversion gain transistor DCX may be provided in the deep element isolation pattern DTI, and the dual conversion gain gate DCG may be provided over the semiconductor pattern 310 in the deep element isolation pattern DTI.

A triple conversion gain gate TCG may be provided over the semiconductor pattern 310. The triple conversion gain gate TCG may cross the semiconductor pattern 310. Specifically, the triple conversion gain gate TCG may extend in the first direction DR1 intersecting the second direction DR2. Therefore, the triple conversion gain transistor TCX may be provided in the deep element isolation pattern DTI, and the triple conversion gain gate TCG may be provided over the semiconductor pattern 310 in the deep element isolation pattern DTI.

In one or more embodiments, a direction in which the reset gate RG, the dual conversion gain gate DCG, and the triple conversion gain gate TCG cross the semiconductor pattern 310 may be the same as a direction in which the first and second source follower gates SFG1 and SFG2 cross the first active region ATR1. For example, the first and second source follower gates SFG1 and SFG2 may cross the first active region ATRI in the first direction DR1, and the reset gate RG, the dual conversion gain gate DCG, and the triple conversion gain gate TCG may also cross the semiconductor pattern 310 in the first direction DR1.

The reset transistor RX, the dual conversion gain transistor DCX, and the triple conversion gain transistor TCX may be arranged in a longitudinal direction of the semiconductor pattern 310. The reset transistor RX, the dual conversion gain transistor DCX, and the triple conversion gain transistor TCX may be spaced apart from each other.

Gates provided over the semiconductor pattern 310 may be collectively referred to as a first gate. For example, the first gate may include at least one of the reset gate RG, the dual conversion gain gate DCG, or the triple conversion gain gate TCG.

In one or more embodiments, the first gate may include at least one of the reset gate RG, the dual conversion gain gate DCG, the triple conversion gain gate TCG, the selection gate SG, the first and second sampling gates SPG1 and SPG2, or the first and second precharge selection gates PCSG1 and PCSG2. For example, FIG. 4 shows that the reset transistor RX, the dual conversion gain transistor DCX, and the triple conversion gain transistor TCX are provided over the semiconductor pattern 310, but the present disclosure is not limited thereto, and at least one of the reset transistor RX, the dual conversion gain transistor DCX, the triple conversion gain transistor TCX, the selection transistor SEL, the first and second sampling transistors SPX1 and SPX2, or the first and second precharge selection transistors PCSEL1 and PCSEL2 may be provided over the semiconductor pattern 310.

Gates provided over at least one active region in the pixel region PXR may be collectively referred to as a second gate. For example, the second gate may include the transfer gate TG and the first and second source follower gates SFG1 and SFG2.

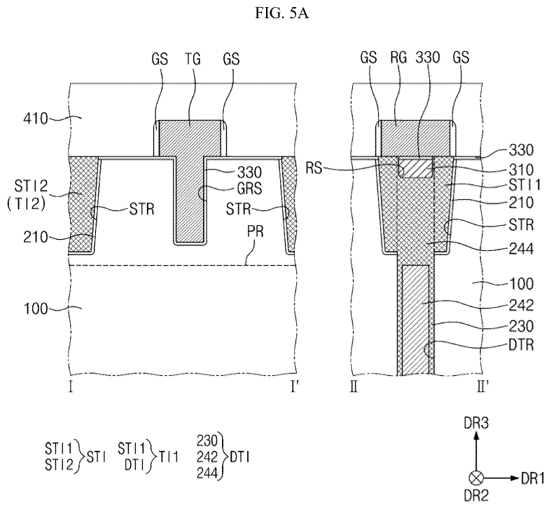

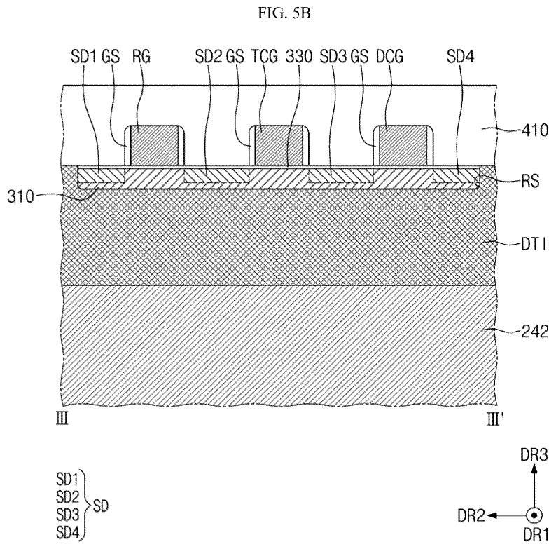

FIG. 5A is cross-sectional views taken along lines I-I′ and II-II′ of FIG. 4. FIG. 5B is a cross-sectional view taken along line III-III′ of FIG. 4.

Referring to FIGS. 5A and 5B, the shallow element isolation pattern STI filling the shallow trench STR may define the second active region ATR2. The shallow element isolation pattern STI may include a first shallow element isolation pattern STII defining the pixel region PXR and a second shallow element isolation pattern STI2 defining at least one active region in the pixel region PXR.

The first shallow element isolation pattern STI1 may be connected to the deep element isolation pattern DTI. The first shallow element isolation pattern STI1 may laterally extend from an upper portion of the deep element isolation pattern DTI. An element isolation pattern defining the pixel region PXR may be collectively referred to as a first element isolation pattern TI1. The first element isolation pattern TII may include the first shallow element isolation pattern STI1 and the deep element isolation pattern DTI.

In addition, an element isolation pattern defining at least one active region in the pixel region PXR may be referred to as a second element isolation pattern TI2. The second element isolation pattern TI2 may include the second shallow element isolation pattern STI2.

The second shallow element isolation pattern STI2 may fill the shallow trench STR recessed the one surface of the substrate 100. The shallow trench STR may define at least one active region. A first insulating liner 210 may be provided between the shallow trench STR and the second shallow element isolation pattern STI2.

A gate recess GRS may be provided in the second active region ATR2. Specifically, the gate recess GRS may be recessed from a portion of an upper surface of the second active region ATR2 (for example, a portion of the one surface of the substrate 100). The gate recess GRS may be adjacent to the photoelectric conversion region PR.

The transfer gate TG may fill the gate recess GRS. Therefore, a lower end of the transfer gate TG may be adjacent to the photoelectric conversion region PR.

A gate insulating layer 330 may be provided on an inner surface of the gate recess GRS. The gate insulating layer 330 may be disposed between the transfer gate TG and the gate recess GRS. The gate insulating layer 330 may be conformally formed. The gate insulating layer 330 may also be formed on the one surface of the substrate 100. The gate insulating layer 330 may also be disposed between the transfer gate TG and the one surface of the substrate 100.

Gate spacers GS may be disposed on side surfaces of the transfer gate TG protruding from the substrate 100. The gate spacers GS may be in contact with the gate insulating layer 330 provided on the one surface of the substrate 100. The gate spacers GS may include at least one of SiCN, SiCON, and SiN.

The first element isolation pattern TI1 may include the first shallow element isolation pattern STI1 defining the pixel region PXR and the deep element isolation pattern DTI extending vertically.

The first shallow element isolation pattern STI1 may be provided at one side of the active region. The first shallow element isolation pattern STI1 may define the pixel region PXR and the active region. The first shallow element isolation pattern STI1 may fill the shallow trench STR recessed from the one surface of the substrate 100. The shallow trench STR may define the pixel regions PXR. The first insulating liner 210 may be provided between the first shallow element isolation pattern STI1 and the shallow trench STR.

In one or more embodiments, the deep element isolation pattern DTI may pass through the first shallow element isolation pattern STI1. Specifically, the deep element isolation pattern DTI may fill the deep trench DTR recessed from one surface of the first shallow element isolation pattern STI1. The deep trench DTR may pass through first shallow element isolation pattern STI1 and extend to the inside of the substrate 100. In this case, the deep trench DTR may also pass through the first insulating liner 210.

Alternatively, in one or more embodiments, the first shallow element isolation pattern STI1 may overlap the deep element isolation pattern DTI. Specifically, the first shallow element isolation pattern STI1 may be provided over the deep element isolation pattern DTI. The first shallow element isolation pattern STI1 and the deep element isolation pattern DTI may vertically overlap each other.

The deep element isolation pattern DTI may include a second insulating liner 230 provided on an inner surface of the deep trench DTR and an internal pattern 242 filling a portion of the deep trench DTR. The second insulating liner 230 may be provided between the internal pattern 242 and the deep trench DTR. The internal pattern 242 may be located under the shallow element isolation pattern STI. Specifically, an upper end of the internal pattern 242 may be located under a lower end of the shallow element isolation pattern STI. The internal pattern 242 may include a semiconductor material in a polycrystalline state. For example, the internal pattern 242 may include polysilicon.

The deep element isolation pattern DTI may include a filling insulating pattern 244 filling a remaining portion of the deep trench DTR. The filling insulating pattern 244 may be provided on the internal pattern 242. The second insulating liner 230 may also be provided between the filling insulating pattern 244 and the deep trench DTR. The second insulating liner 230 may also be provided between the filling insulating pattern 244 and the shallow element isolation pattern STI. The filling insulating pattern 244 may be provided in the shallow element isolation pattern STI.

In FIG. 5A, for convenience of explanation, a boundary between the shallow element isolation pattern STI and the deep element isolation pattern DTI is shown, but the boundary may not substantially exist. For example, in an actual product, the boundary between the deep element isolation pattern DTI and the shallow element isolation pattern STI may not exist.

A recess RS in which the semiconductor pattern 310 is provided may be formed in the first element isolation pattern TI1. The recess RS may be recessed from one surface of the first element isolation pattern TI1. Specifically, the recess RS may be recessed from one surface of the deep element isolation pattern DTI. More specifically, the recess RS may be recessed from one surface of the filling insulating pattern 244.

Alternatively, in one or more embodiments, the recess RS may also be recessed from one surface of the first shallow element isolation pattern STI1.

The semiconductor pattern 310 may be provided in the recess RS in the first element isolation pattern TI1. An upper surface of the semiconductor pattern 310 may be located under an upper surface of the first shallow element isolation pattern STI1.

The gate insulating layer 330 may be provided on the upper surface of the semiconductor pattern 310 exposed through the recess RS. The gate insulating layer 330 may also be provided on the one surface of the substrate 100.

The reset gate RG may be provided over the semiconductor pattern 310 on which the gate insulating layer 330 is formed. The reset gate RG may cross the semiconductor pattern 310. The reset gate RG may extend in a direction intersecting the longitudinal direction of the semiconductor pattern 310.

The gate spacers GS may also be provided on side surfaces of the reset gate RG protruding from the one surface of the substrate 100.

The dual conversion gain gate DCG may be provided over the semiconductor pattern 310 on which the gate insulating layer 330 is formed. The dual conversion gain gate DCG may cross the semiconductor pattern 310. The dual conversion gain gate DCG may extend in the direction intersecting the longitudinal direction of the semiconductor pattern 310. The dual conversion gain gate DCG may be spaced apart from the reset gate RG in the longitudinal direction of the semiconductor pattern 310. For example, the dual conversion gain gate DCG may be spaced apart from the reset gate RG in a direction parallel to the second direction DR2 and may extend in the first direction DR1.

The gate spacers GS may also be provided on side surfaces of the dual conversion gain gate DCG protruding from the one surface of the substrate 100.

The triple conversion gain gate TCG may be provided over the semiconductor pattern 310 on which the gate insulating layer 330 is formed. The triple conversion gain gate TCG may cross the semiconductor pattern 310. The triple conversion gain gate TCG may extend in the direction intersecting the longitudinal direction of the semiconductor pattern 310. The triple conversion gain gate TCG may be spaced apart from the reset gate RG in the longitudinal direction of the semiconductor pattern 310. For example, the triple conversion gain gate TCG may be spaced apart from the reset gate RG in the direction parallel to the second direction DR2 and may extend in the first direction DR1. The triple conversion gain gate TCG may be provided between the reset gate RG and the dual conversion gain gate DCG.

The gate spacers GS may also be provided on side surfaces of the triple conversion gain gate TCG protruding from the one surface of the substrate 100.

The semiconductor pattern 310 may include a plurality of source/drain regions SD and a channel region located between the source/drain regions SD. Specifically, the semiconductor pattern 310 may include a pair of source/drain regions SD located at both ends in the longitudinal direction. The semiconductor pattern 310 may include at least one source/drain region SD provided in every space between the plurality of first gates located over the semiconductor pattern 310. For example, the semiconductor pattern 310 may include a first source/drain region SD1 located at one side of the reset gate RG, a second source/drain region SD2 located between the reset gate RG and the triple conversion gain gate TCG, a third source/drain region SD3 located between the triple conversion gain gate TCG and the dual conversion gain gate DCG, and a fourth source/drain region SD4 located at one side of the dual conversion gain gate DCG. Each of the channel regions may be provided under the reset gate RG, the triple conversion gain gate TCG, and the dual conversion gain gate DCG.

An interlayer insulating layer 410 may be provided over the one surface of the substrate 100. The interlayer insulating layer 410 may cover the semiconductor pattern 310, the reset gate RG, the triple conversion gain gate TCG, and the dual conversion gain gate DCG. The interlayer insulating layer 410 may include an insulating material. For example, the interlayer insulating layer 410 may include at least one of silicon oxide, silicon nitride, or silicon oxynitride.

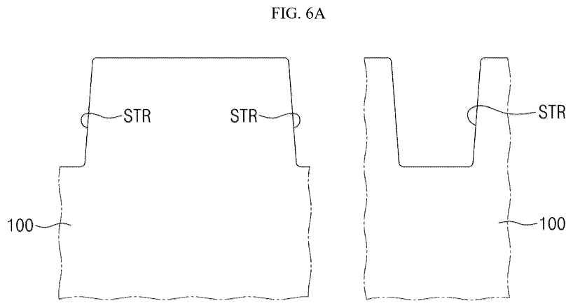

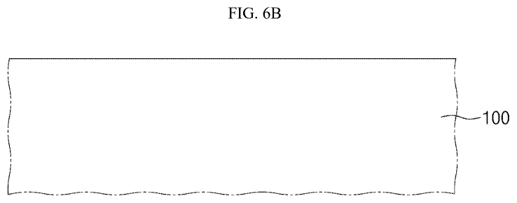

FIGS. 6A, 7A, 8, and 9A to 15A are cross-sectional views for showing a method of manufacturing the image sensor 10 according to one or more embodiments of the present disclosure, which are cross-sectional views corresponding to lines I-I′ and II-II′ of FIG. 4. FIGS. 6B, 7B, 9B, 10B to 15B, and 16 are cross-sectional views for showing the method of manufacturing the image sensor 10 according to one or more embodiments of the present disclosure, which are cross-sectional views corresponding to line III-III′ of FIG. 4.

Referring to FIGS. 6A and 6B, a shallow trench STR may be formed in a substrate 100. The shallow trench STR may be formed by patterning the substrate 100. The shallow trench STR may be recessed from one surface of the substrate 100. Some of the shallow trenches STR may define pixel regions PXR, and the remaining some of the shallow trenches STR may define at least one active region.

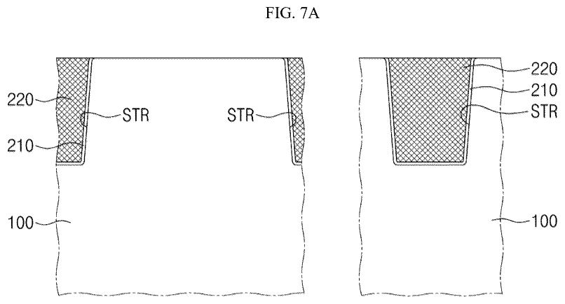

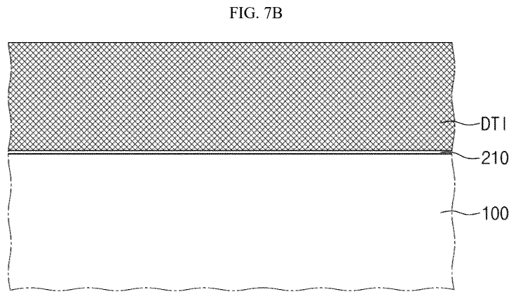

Referring to FIGS. 7A and 7B, a first insulating liner 210 may be formed on inner surfaces of the shallow trench STR. The first insulating liner 210 may include at least one of silicon oxide, silicon nitride, or silicon oxynitride. For example, the first insulating liner 210 may include a dual liner having a double layer composed of one insulating liner including silicon nitride and another insulating liner including silicon oxide, however the present disclosure is not limited thereto and other combinations of suitable insulating materials may also be used.

A shallow element isolation pattern STI may fill the shallow trench STR in which the first insulating liner 210 is formed. The shallow element isolation pattern STI may include a first shallow element isolation pattern STI1 defining the pixel regions PXR and a second shallow element isolation pattern STI2 defining at least one active region in the pixel region PXR. The first shallow element isolation pattern STI1 may fill some of the shallow trenches STR, and the second shallow element isolation pattern may fill the remaining some of the shallow trenches STR.

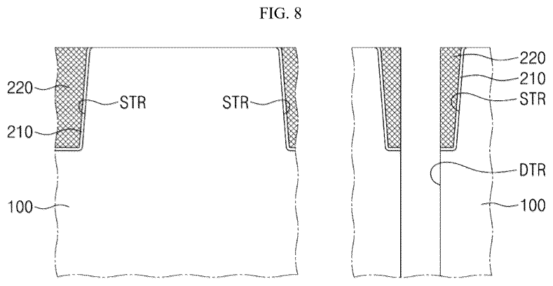

Referring to FIG. 8, a deep trench DTR defining the pixel region PXR may be formed in the substrate 100. The deep trench DTR may be formed by patterning the substrate 100 in which the shallow element isolation pattern STI is formed. Specifically, the deep trench DTR may be formed in the first shallow element isolation pattern STI1 by patterning the first shallow element isolation pattern STI1.

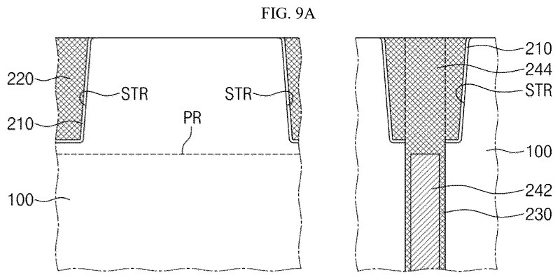

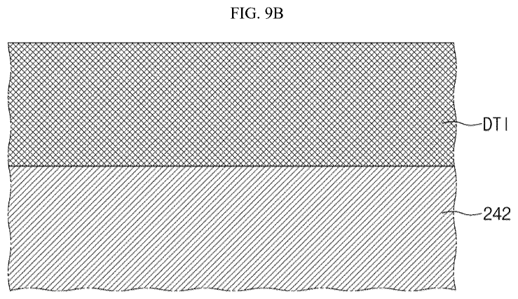

Referring to FIGS. 9A and 9B, a deep element isolation pattern DTI filling the deep trench DTR may be formed. Specifically, forming the deep element isolation pattern DTI may include forming a second insulating liner 230 on inner surfaces of the deep trench DTR, forming an internal pattern 242 filling a portion of the deep trench DTR in which the second insulating liner 230 is formed, and forming a filling insulating pattern 244 filling a remaining portion of the deep trench DTR in which the internal pattern 242 is formed. After the internal pattern 242 is formed, the filling insulating pattern 244 may be formed.

The second insulating liner 230 may include at least one of silicon oxide, silicon nitride, or silicon oxynitride. The internal pattern 242 may include polysilicon. The filling insulating pattern 244 may include at least one of silicon oxide, silicon nitride, or silicon oxynitride.

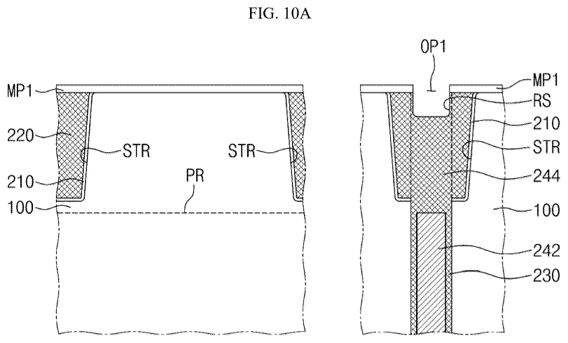

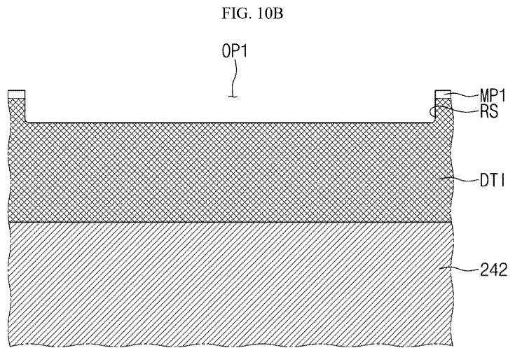

Referring to FIGS. 10A and 10B, a first mask pattern MP1 having a first opening OPI may be formed over the one surface of the substrate 100 in which the deep element isolation pattern DTI is formed. The first opening OP1 may define a recess RS. The first mask pattern MP1 may cover the active region in the pixel.

An etching process may be performed using the first mask pattern MP1 as an etching mask. A first element isolation pattern TII exposed through the first opening OP1 of the first mask pattern MP1 may be etched. Specifically, the filling insulating pattern 244 exposed through the first opening OP1 may be etched to form the recess RS. The recess RS may be formed in the filling insulating pattern 244.

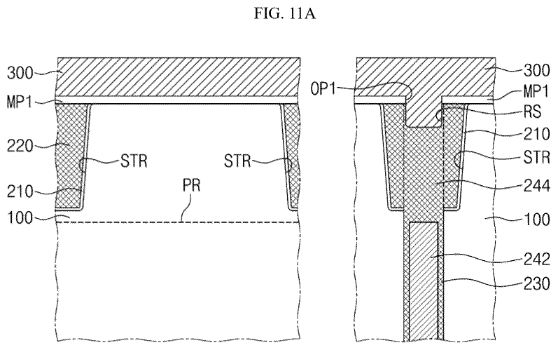

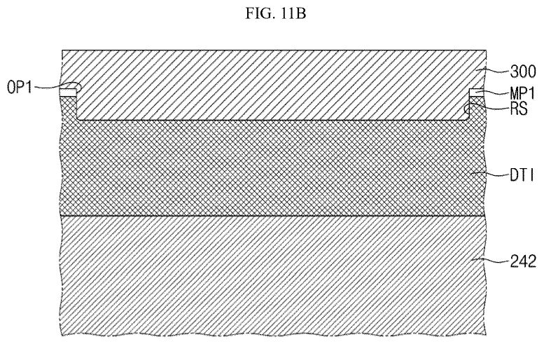

Referring to FIGS. 11A and 11B, a semiconductor film 300 filling the recess RS may be formed over the one surface of the substrate 100. The semiconductor film 300 may include a semiconductor material in an amorphous state or a polycrystalline state. The semiconductor film 300 may also fill the first opening OP1 of the first mask pattern MP1.

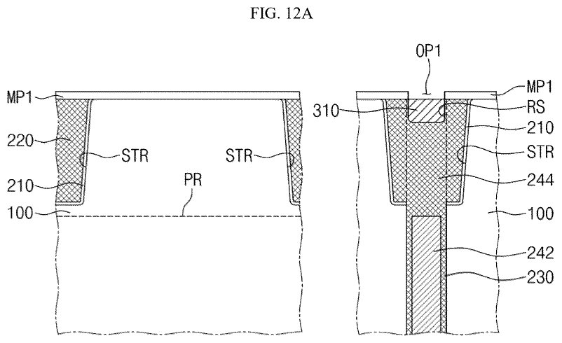

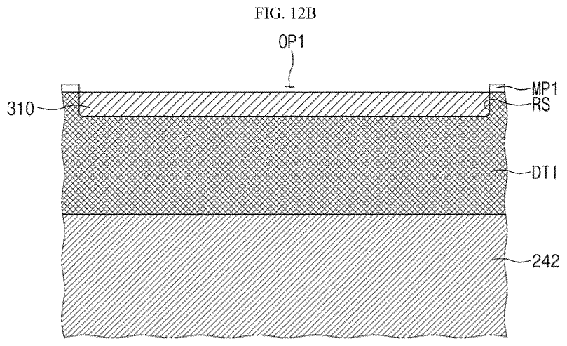

Referring to FIGS. 12A and 12B, a semiconductor pattern 310 may be formed in the recess RS. The semiconductor pattern 310 may be formed by planarizing the semiconductor film 300 formed on the first mask pattern MP1. The planarization of the semiconductor film 300 may be performed using an etch back process or a chemical mechanical polishing (CMP) process.

The semiconductor film 300 may be planarized until the first mask pattern MP1 is exposed. In addition, during the planarization process, a portion of the semiconductor film 300 remaining in the first opening OP1 may also be removed. Therefore, the semiconductor pattern 310 in the recess RS may be formed. After the semiconductor pattern 310 is formed, the first mask pattern MP1 may be removed.

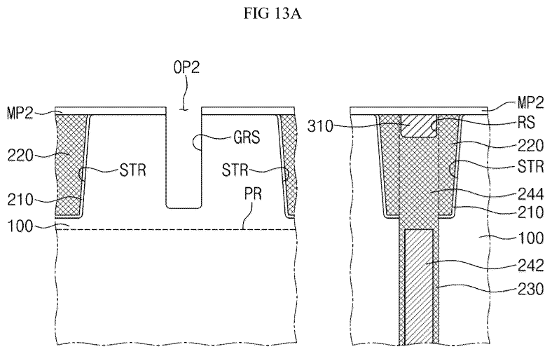

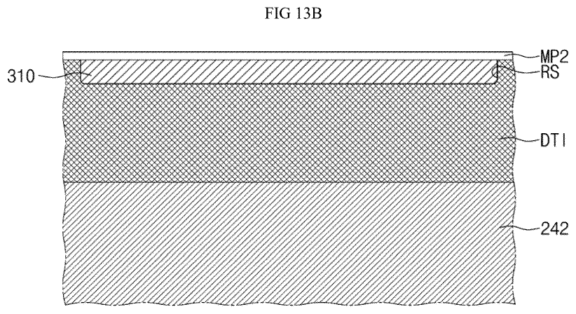

Referring to FIGS. 13A and 13B, a gate recess GRS may be formed in the substrate 100. Specifically, the gate recess GRS may be formed in the active region.

Forming the gate recess GRS may include forming a second mask pattern MP2 and performing an etching process using the second mask pattern MP2 as an etching mask. The second mask pattern MP2 may be formed over the one surface of the substrate 100 in which the semiconductor pattern 310 is formed. The second mask pattern MP2 may have a second opening OP2 defining the gate recess GRS.

The active region exposed through the second opening OP2 may be etched using the second mask pattern MP2 as an etching mask. Accordingly, the gate recess GRS located under the second opening OP2 may be formed. A bottom surface of the gate recess GRS may be adjacent to a photoelectric conversion region PR. After the gate recess GRS is formed, the second mask pattern MP2 may be removed.

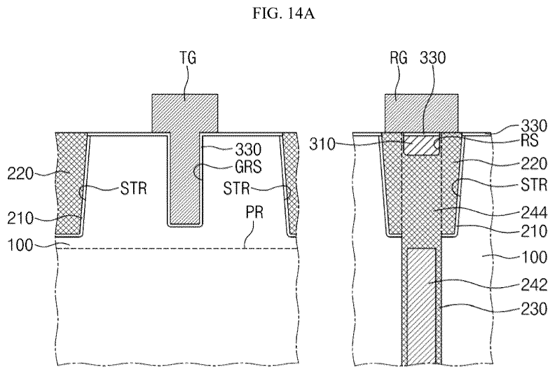

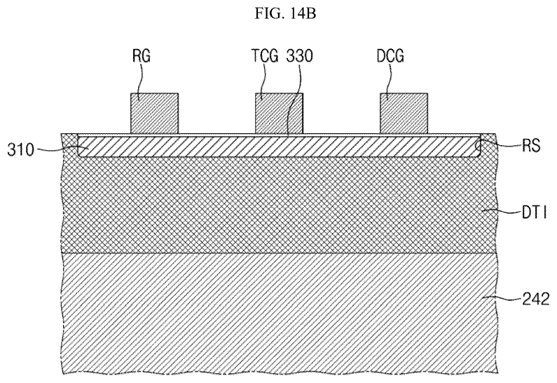

Referring to FIGS. 14A and 14B, a gate insulating layer 330 may be formed on the one surface of the substrate 100 in which the gate recess GRS is formed. The gate insulating layer 330 may conformally cover the one surface of the substrate 100 and an inner surface of the gate recess GRS. In addition, the gate insulating layer 330 may be formed on an upper surface of the semiconductor pattern 310.

A transfer gate TG filling the gate recess GRS in which the gate insulating layer 330 is formed, and a reset gate RG over the semiconductor pattern 310 in which the gate insulating layer 330 is formed, may be formed. Specifically, a conductive layer may be formed over the one surface of the substrate 100 in which the gate insulating layer 330 is formed. The conductive layer may fill the gate recess GRS in which the gate insulating layer 330 is formed and may cover the semiconductor pattern 310 in which the gate insulating layer 330 is formed. The conductive layer may cover the one surface of the substrate 100 in which the gate insulating layer 330 is formed. The conductive layer may include at least one of a doped semiconductor material (e.g., doped polysilicon), a metal (e.g., tungsten, titanium, aluminum, tantalum, etc.), a conductive metal nitride (e.g., titanium nitride, tantalum nitride, etc.), or a conductive metal-semiconductor compound (e.g., metal silicide, etc.).

The conductive layer may be patterned to form the transfer gate TG and the reset gate RG. The transfer gate TG may be located over the active region, and the reset gate RG may be located over the first element isolation pattern TI1.

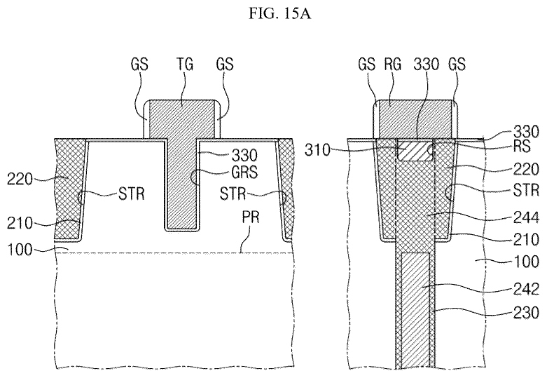

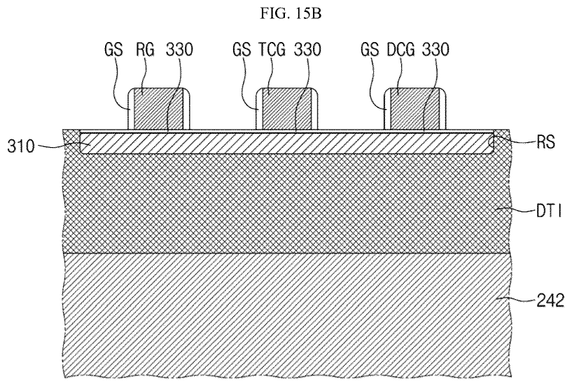

Referring to FIGS. 15A and 15B, gate spacers GS may be formed on side surfaces of the transfer gate TG and on side surfaces of the reset gate RG. Specifically, the gate spacers GS may be formed on the side surfaces of the transfer gate TG protruding from the one surface of the substrate 100. In addition, the gate spacers GS may be formed on the side surfaces of the reset gate RG protruding from one surface of the first element isolation pattern TI1.

Specifically, forming the gate spacers GS may include conformally forming a spacer film over the one surface of the substrate 100 in which the transfer gate TG and the reset gate RG are formed, and anisotropically etching the spacer film to form the gate spacers GS.

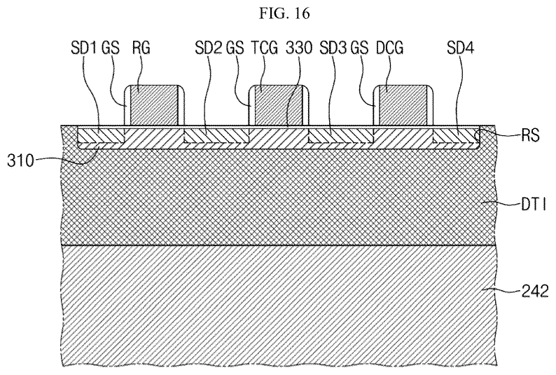

Referring to FIG. 16, source/drain regions SD and at least one channel region (no reference numeral) may be formed in the semiconductor pattern 310. Specifically, first to fourth source/drain regions SD1, SD2, SD3, and SD4 and channel regions therebetween may be formed in the semiconductor pattern 310.

The source/drain regions SD may be formed by an ion implantation process. An ion implantation process may be performed over the one surface of the substrate 100 over which the gate spacers GS are formed. In this case, the gate spacers GS may prevent ions from being implanted into the substrate. Accordingly, edges of the source/drain regions SD may be vertically aligned with edges of the gate spacers GS.

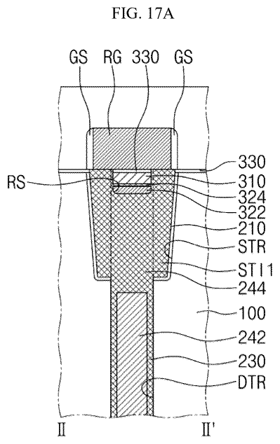

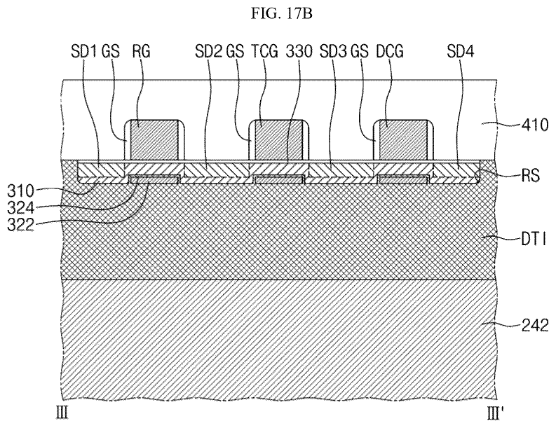

FIG. 17A is a cross-sectional view of an image sensor 10 according to one or more embodiments of the present disclosure, which is a cross-sectional view corresponding to line II-II′ of FIG. 4. FIG. 17B is a cross-sectional view of the image sensor 10 according to one or more embodiments of the present disclosure, which is a cross-sectional view corresponding to line III-III′ of FIG. 4.

Components constituting the image sensor 10 described below and materials forming the components may be substantially the same as or similar to those of the image sensor 10 described above with reference to FIGS. 5A and 5B. Therefore, for convenience of explanation, differences from the above-described image sensor 10 will be mainly described.

Referring to FIGS. 17A and 17B, a buried gate 322 may be provided in the recess RS. The buried gate 322 may be provided under the semiconductor pattern 310. The buried gate 322 may include a conductive material. For example, the buried gate 322 may include at least one of a doped semiconductor material (e.g., doped polysilicon), a metal (e.g., tungsten, titanium, aluminum, tantalum, etc.), a conductive metal nitride (e.g., titanium nitride, tantalum nitride, etc.), or a conductive metal-semiconductor compound (e.g., metal silicide, etc.).

The buried gate 322 may be electrically connected to the first gate over the semiconductor pattern 310. For example, the buried gate 322 may be electrically connected to the reset gate RG over the semiconductor pattern 310. The buried gate 322 may be provided under the first gate over the semiconductor pattern 310. The buried gate 322 may be located under the channel region of the semiconductor pattern 310. Accordingly, a voltage may be simultaneously applied through the buried gate 322 and the reset gate RG, and a channel may be formed along an upper surface and a lower surface of the semiconductor pattern 310. Therefore, a channel width of the transistor may be increased.

A buried gate insulating layer 324 may be formed between the buried gate 322 and the semiconductor pattern 310. The buried gate insulating layer 324 may intervene between the buried gate 322 and the semiconductor pattern 310 to maintain separation thereof. The buried gate insulating layer 324 may cover the buried gate 322.

The buried gate 322 may also be provided under the triple conversion gain gate TCG or the dual conversion gain gate DCG. In this case, the triple conversion gain gate TCG and the buried gate 322 provided under the triple conversion gain gate TCG may be electrically connected. In addition, the dual conversion gain gate DCG and the buried gate 322 provided under the dual conversion gain gate DCG may be electrically connected.

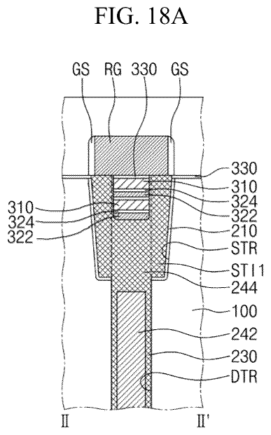

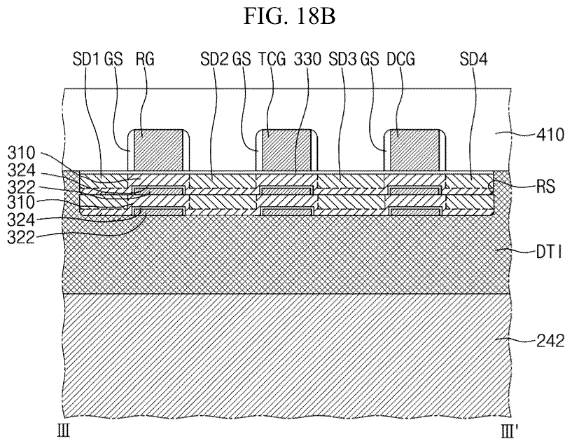

In one or more embodiments, referring to FIGS. 18A and 18B, a plurality of semiconductor patterns 310 may be stacked in the recess RS. The semiconductor patterns 310 may be vertically spaced apart from each other. The buried gate 322 may further include at least one buried gate provided in every space between the semiconductor patterns 310. The buried gate insulating layer 324 may also be provided between the semiconductor patterns 310 and the buried gate between the semiconductor patterns 310. Therefore, a transistor having a plurality of stacked channel regions may be provided.

According to one or more embodiments of the present disclosure, an image sensor may include a semiconductor pattern provided in an element isolation pattern, a first gate crossing the semiconductor pattern, and a gate insulating layer provided between the first gate and the semiconductor pattern, so that some transistors can be disposed outside an active region. Therefore, a channel width of the remaining transistors disposed in the active region can be increased. Specifically, a channel width of a source follower transistor disposed in the active region can be increased. Accordingly, performance of the image sensor can be improved.

In addition, according to one or more embodiments of the present disclosure, because the semiconductor pattern may be provided in a first element isolation pattern existing in most image sensors, a structure of the image sensor of the present disclosure can be widely applied to image sensors having various layouts.

In addition, according to one or more embodiments of the present disclosure, because a reset transistor, which has relatively low correlation with characteristics of the image sensor among the transistors, is disposed over the first element isolation pattern, degradation in the performance of the image sensor due to the semiconductor pattern having a polycrystalline state can be minimized.

In addition, according to one or more embodiments of the present disclosure, because a conversion gain transistor, which has relatively low correlation with characteristics of the image sensor among the transistors, is disposed over the first element isolation pattern, the degradation in the performance of the image sensor due to a semiconductor pattern having a polycrystalline state can be minimized.

In addition, according to one or more embodiments of the present disclosure, the image sensor may include a plurality of conversion gain transistors electrically connected to a floating diffusion region, thereby providing various pluralities of conversion gain modes. Accordingly, the performance of the image sensor can be improved.

In addition, according to one or more embodiments of the present disclosure, transistors crossing the active region in the same direction as a direction in which a source follower gate crosses the active region may be relocated onto the first element isolation pattern, so that the channel width of the source follower gate can be increased. Therefore, the performance of the image sensor can be improved.

The above-described contents are specific embodiments for implementing the present disclosure. In addition to the above-described embodiments, the present disclosure will also include embodiments that can be simply designed around or easily changed. In addition, the present disclosure will also include technologies that can be implemented by being easily modified using the embodiments. Therefore, the scope of the present disclosure should not be limited to the above-described embodiments, but should be determined not only by the appended claims but also by the equivalents of the claims of the present disclosure.

One or more embodiments provide an image sensor with improved performance.

One or more embodiments of the present disclosure also provide an image sensor which may have reduced noise.

One or more embodiments of the present disclosure also provide an image sensor having a plurality of conversion gain modes.

One or more embodiments of the present disclosure also provide an image sensor in which a channel width of a source follower transistor is increased.

One or more embodiments of the present disclosure also provide an image sensor in which an arrangement area of a source follower transistor is increased.

According to an aspect of the disclosure, a method of manufacturing an image sensor may include forming an element isolation pattern including an insulating material in a substrate, patterning the element isolation pattern to form a recess in the element isolation pattern, forming a semiconductor pattern filling the recess, forming a gate insulating layer on the semiconductor pattern, and forming at least one first gate crossing the semiconductor pattern on the gate insulating layer.

The forming of the element isolation pattern may include forming a shallow element isolation pattern filling a shallow trench formed by patterning the substrate, and forming a deep element isolation pattern filling a deep trench formed by patterning the shallow element isolation pattern.

The forming of the shallow element isolation pattern may include forming a first insulating liner on an inner surface of the shallow trench, and forming the shallow element isolation pattern filling the shallow trench in which the first insulating liner is formed.

The forming of the deep element isolation pattern may include forming a second insulating liner on an inner surface of the deep trench, forming an internal pattern filling a portion of the deep trench in which the second insulating liner is formed, and forming a filling insulating pattern filling a remaining portion of the deep trench.

The forming of the recess may include forming a first mask pattern having a first opening defining the recess on the substrate and the element isolation pattern, and performing an etching process using the first mask pattern as an etching mask to form the recess in the filling insulating pattern.

The forming of the semiconductor pattern may include forming a semiconductor film on the first mask pattern, the semiconductor film filling the recess, and planarizing the semiconductor film so that an upper surface of the first mask pattern is exposed, wherein, during the planarization of the semiconductor film, a portion of the semiconductor film in the recess exposed through the first opening may also be removed.

The method of manufacturing an image sensor according to one embodiment of the present disclosure may further include, after the semiconductor pattern is formed, forming a second mask pattern having a second opening defining a gate recess on the substrate, and performing an etching process using the second mask pattern as an etching mask to form the gate recess to be filled with a transfer gate.

During the formation of the gate insulating layer on the semiconductor pattern, the gate insulating layer may also be formed on an inner surface of the gate recess.

During the formation of the first gate, the transfer gate filling the gate recess may also be formed.

The semiconductor pattern may have a polycrystalline state.

What is claimed is:

1. An image sensor, comprising:
a first element isolation pattern in a substrate adjacent one or more pixel regions, wherein each of the one or more pixel regions comprise a second element isolation pattern and at least one active region, and the second element isolation pattern is in the substrate and adjacent the at least one active region;
a semiconductor pattern in a recess in a surface of the first element isolation pattern, the semiconductor pattern comprising a polycrystalline semiconductor material;
at least one first gate on the semiconductor pattern; and
a gate insulating layer between the at least one first gate and the semiconductor pattern.

2. The image sensor of claim 1, wherein the first element isolation pattern comprises:
a first shallow element isolation pattern adjacent a first side of the at least one active region; and
a deep element isolation pattern in the first shallow element isolation pattern and extending vertically with respect to a top surface of the substrate.

3. The image sensor of claim 2, wherein the first shallow element isolation pattern is in a shallow trench that is recessed from the top surface of the substrate, and wherein the deep element isolation pattern is in a deep trench that is recessed from a surface of the first shallow element isolation pattern.

4. The image sensor of claim 3, further comprising:
a first insulating liner between the shallow trench and the first shallow element isolation pattern,
wherein the deep element isolation pattern extends through the first insulating liner.

5. The image sensor of claim 3, wherein the deep element isolation pattern comprises:
a second insulating liner on an inner surface of the deep trench;
an internal pattern in a portion of the deep trench; and
a filling insulating pattern on the internal pattern and in a remaining portion of the deep trench.

6. The image sensor of claim 5, wherein the internal pattern comprises a polycrystalline material.

7. The image sensor of claim 6, wherein the surface of the first element isolation pattern is a surface of the filling insulating pattern.

8. The image sensor of claim 1, wherein the at least one first gate comprises first gates spaced apart from each other on the semiconductor pattern.

9. The image sensor of claim 8, wherein the first gates comprise a reset gate adjacent a floating diffusion region.

10. The image sensor of claim 9, wherein the first gates further comprise at least one conversion gain gate adjacent the floating diffusion region.

11. An image sensor comprising:
an element isolation pattern in a substrate and comprising an insulating material;
a semiconductor pattern in a recess in the element isolation pattern and comprising a polycrystalline semiconductor material;
at least one first gate on the semiconductor pattern;
at least one second gate on at least one active region adjacent a first side of the element isolation pattern; and
a gate insulating layer between the at least one first gate and the semiconductor pattern, and between the at least one second gate and the at least one active region.

12. The image sensor of claim 11, wherein the element isolation pattern comprises:
a deep element isolation pattern in the substrate adjacent one or more pixel regions; and
a shallow element isolation pattern in the substrate adjacent the at least one active region, and
wherein the shallow element isolation pattern and the at least one active region are in each of the one or more pixel regions.

13. The image sensor of claim 12, wherein the recess is in a surface of the deep element isolation pattern.

14. The image sensor of claim 12, further comprising:
a first insulating liner between the shallow element isolation pattern and the substrate,
wherein the deep element isolation pattern extends through the shallow element isolation pattern and the first insulating liner.

15. The image sensor of claim 12, wherein the deep element isolation pattern comprises:
a second insulating liner on an inner surface of a deep trench extending through the shallow element isolation pattern;
an internal pattern in a portion of the deep trench; and
a filling insulating pattern in a remaining portion of the deep trench,
wherein the recess is in the filling insulating pattern.

16. The image sensor of claim 11, wherein the at least one first gate comprises first gates spaced apart from each other on the semiconductor pattern,
wherein the semiconductor pattern further comprises source/drain regions at respective end portions thereof, and
wherein the source/drain regions are between the first gates.

17. The image sensor of claim 11, wherein the at least one active region comprises a first active region and a second active region, and
wherein the at least one second gate comprises a source follower gate on the first active region and a transfer gate on the second active region.

18. The image sensor of claim 17, wherein the source follower gate extends over the first active region in a first direction, and
wherein the at least one first gate extends over the semiconductor pattern in the first direction.

19. An image sensor comprising:
an element isolation pattern in a substrate and comprising an insulating material;
at least one semiconductor pattern in a recess in the element isolation pattern and comprising a polycrystalline semiconductor material;
a first gate on the at least one semiconductor pattern;
a buried gate in the recess and below the at least one semiconductor pattern;
a buried gate insulating layer between the buried gate and the at least one semiconductor pattern; and
a gate insulating layer between the first gate and the at least one semiconductor pattern.

20. The image sensor of claim 19, wherein
the at least one semiconductor pattern comprises semiconductor patterns vertically stacked apart from each other, and
the buried gate further comprises at least one buried gate between adjacent ones of the semiconductor patterns.
